(19) United States
(12) Patent Application Publication
(10) Pub. No.: US 2024/0222419 A1
(43) Pub. Date: Jul. 4, 2024

(54) DISPLAY DEVICE

(71) Applicant: LG Display Co., Ltd., Seoul (KR)

(72) Inventors: Minseok KIM, Seoul (KR); Jongsung KIM, Seoul (KR); Yongmin HA, Seoul (KR)

(21) Appl. No.: 18/538,068

(22) Filed: Dec. 13, 2023

(30) Foreign Application Priority Data
Dec. 30, 2022 (KR) 10-2022-0190884

(51) Int. Cl. H01L 27/15; H01L 33/40; H01L 33/44; H01L 33/60; H01L 33/62

(52) U.S. Cl. CPC H01L 27/156; H01L 33/405; H01L 33/44; H01L 33/60; H01L 33/62

(57) ABSTRACT

A display device includes a wiring substrate on which a plurality of first link wiring lines transmitting a first signal and a plurality of second link wiring lines transmitting a second signal are disposed, wherein a plurality of first group of light-emitting elements are disposed on the wiring substrate; a plurality of display units disposed on and bonded to the wiring substrate, wherein the plurality of display units are spaced apart from each other, wherein a plurality of second group of light-emitting elements are disposed in each of the plurality of display units; a reflective bonding layer positioned between the wiring substrate and the plurality of display units; and a plurality of bonding members disposed between the display units and the wiring substrate, wherein the plurality of bonding members respectively overlap the plurality of the first link wiring lines and the plurality of the second link wiring lines.

### CROSS-REFERENCE TO RELATED APPLICATION

This application claims priority from Korean Patent Application No. 10-2022-0190884 filed on Dec. 30, 2022, in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display device, and more particularly, to a display device in which a plurality of display units is disposed on a wiring substrate on which a plurality of link wiring lines are disposed.

### Description of the Related Art

A display device is applied to various electronic devices such as TVs, mobile phones, laptops and tablets. To this end, research to develop thinning, lightening, and low power consumption of the display device is continuing.

Among display devices, a light-emitting display device has a light-emitting element or a light source built therein and displays information using light generated from the built-in light-emitting element or light source. A display device including a self-light-emitting element may be implemented to be thinner than a display device with the built-in light source, and may be implemented as a flexible display device that may be folded, bent, or rolled.

The display device having the self-light-emitting element may include, for example, an organic light-emitting display device (OLED) including a light-emitting layer made of an organic material, or a micro LED display device (micro light-emitting diode display device) including a light-emitting layer made of an inorganic material.

### BRIEF SUMMARY

The inventors have recognized that OLEDs and the micro LEDs both have advantages and disadvantages. In this regard, the organic light-emitting display device (OLED) does not require a separate light source. However, due to material characteristics of the organic material, the organic material is vulnerable to foreign external materials such as moisture and oxygen. Accordingly, the inventors have realized that a defective pixel might occur in the organic light-emitting display device due to these external materials being present near an OLED display device. On the contrary, the micro LED display device includes the light-emitting layer made of the inorganic material that is resistant to moisture and oxygen and thus is not affected by the external materials and thus has high reliability and has a long lifespan compared to the organic light-emitting display device.

One or more embodiments of the present disclosure provide a large-area transparent display device in which a plurality of display units are disposed on a wiring substrate on which a plurality of link wiring lines are disposed.

Further, one or more embodiments of the present disclosure provide a display device in which different signals are input into one display device such that different images are respectively outputted from both opposing surfaces of the display device to an outside out of the device.

Further, one or more embodiments of the present disclosure provide a display device in which one thin-film transistor drives a plurality of first group of light-emitting elements disposed on a wiring substrate or a plurality of second group of light-emitting elements disposed on a display unit.

Further, one or more embodiments of the present disclosure provide a display device in which a bezel area is minimum or substantially absent to realize a zero bezel area (e.g., a display device that does not have a bezel area).

The technical benefits according to the present disclosure are not limited to the above-mentioned benefits. Other benefits and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

An aspect of the present disclosure provides a display device comprising: a wiring substrate on which a plurality of first link wiring lines transmitting a first signal and a plurality of second link wiring lines transmitting a second signal different from the first signal are disposed, wherein a plurality of first group of light-emitting elements are disposed on the wiring substrate; a plurality of display units disposed on the wiring substrate, wherein the plurality of display units are spaced apart from each other, wherein a plurality of second group of light-emitting elements disposed in each of the plurality of display units; a reflective bonding layer positioned between the wiring substrate and the plurality of display units; and a plurality of bonding members disposed between the display units and the wiring substrate, wherein the plurality of bonding members respectively overlap the plurality of the first link wiring lines and the plurality of the second link wiring lines.

According to an embodiment of the present disclosure, the display device includes the wiring substrate on which the plurality of first link wiring lines transmitting the first signal and the plurality of second link wiring lines transmitting the second signal different from the first signal are disposed, wherein the plurality of first group of light-emitting elements are disposed on the wiring substrate; and the plurality of display units disposed on and bonded to the wiring substrate, wherein the plurality of display units are spaced apart from each other, wherein the plurality of second group of light-emitting elements different from the plurality of first group of light-emitting elements are disposed in each of the plurality of display units. The plurality of first group of light-emitting elements respectively overlap the plurality of second group of light-emitting elements. Thus, a large-area transparent display device may be realized.

Further, according to an embodiment of the present disclosure, the display device in which different signals are input into one display device such that different images are respectively outputted from both opposing surfaces of the display device to an outside out of the device may be provided.

Further, one thin-film transistor drives the light-emitting element disposed on the wiring substrate and the light-emitting element disposed in the display unit, thereby unifying parts with other and thus manufacturing the eco-friendly product.

Further, a refractive index matching layer may be disposed between adjacent display units to improve transparency. Thus, a display device in which a bezel area is minimum or substantially absent to realize a zero-bezel area may be realized.

Effects of the present disclosure are not limited to the effects mentioned above, and other effects not mentioned will be clearly understood by those skilled in the art from the descriptions below.

### BRIEF DESCRIPTION OF THE SEVERAL VIEWS OF THE DRAWINGS

FIG. 1 is a schematic plan view of a display device according to an embodiment of the present disclosure.

FIG. 2 is a schematic plan view of a wiring substrate according to one embodiment of the present disclosure.

FIG. 3 is a cross-sectional view of 3 in FIG. 2.

FIG. 4 is a schematic enlarged plan view of 4 in FIG. 1.

FIG. 5 is a schematic enlarged plan view of 5 in FIG. 4.

FIG. 6A is a cross-sectional view of 6 in FIG. 4.

FIG. 6B is another cross-sectional view of 6 in FIG. 4 according to another embodiment of the present disclosure.

FIG. 7 is a schematic enlarged plan view of 7 of FIG. 2 of the display device according to one embodiment of the present disclosure.

FIG. 8 is a cross-sectional view of 8 in FIG. 7.

FIG. 9 is a schematic cross-sectional view of 9 in FIG. 1.

FIG. 10 is a schematic enlarged plan view of 10 in FIG. 9.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed below, but may be implemented in various different forms. Thus, these embodiments are set forth only to make the present disclosure complete, and to completely inform the scope of the present disclosure to those of ordinary skill in the technical field to which the present disclosure belongs.

A shape, a size, a dimension (e.g., length, width, height, thickness, radius, diameter, area, etc.), a ratio, an angle, a number of elements, etc., disclosed in the drawings for describing the embodiments of the present disclosure are exemplary, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise,” “including,” “include,” and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to,” or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after,” “subsequent to,” “before,” etc., another event may occur therebetween unless “directly after”, “directly subsequent” or “directly before” is not indicated.

It will be understood that, although the terms “first,” “second,” “third,” and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

It will be understood that when an element or layer is referred to as being “connected to,” or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various embodiments of the present disclosure may be partially or entirely combined with each other, and may be technically associated with each other or operate with each other. The embodiments may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display device according to each embodiment of the present disclosure will be described with reference to the accompanying drawings.

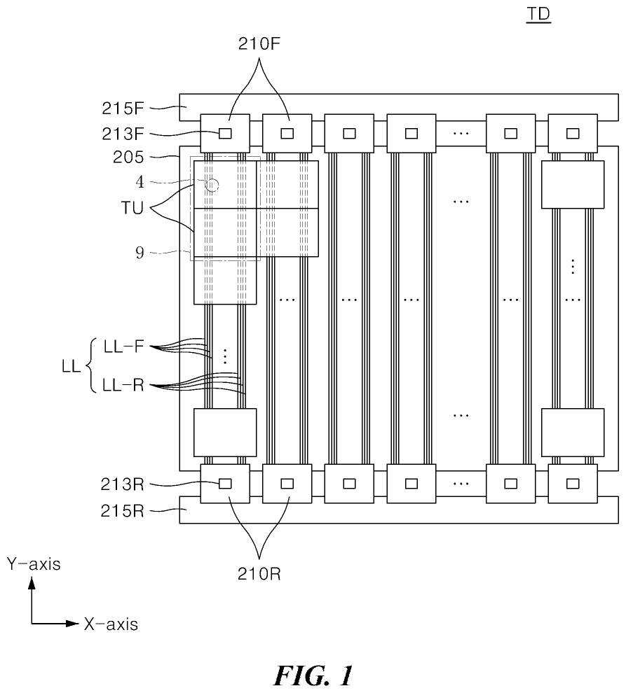

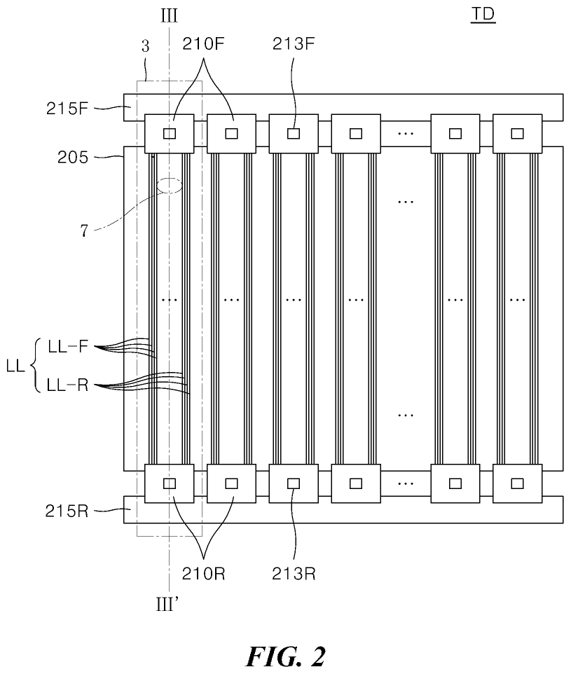

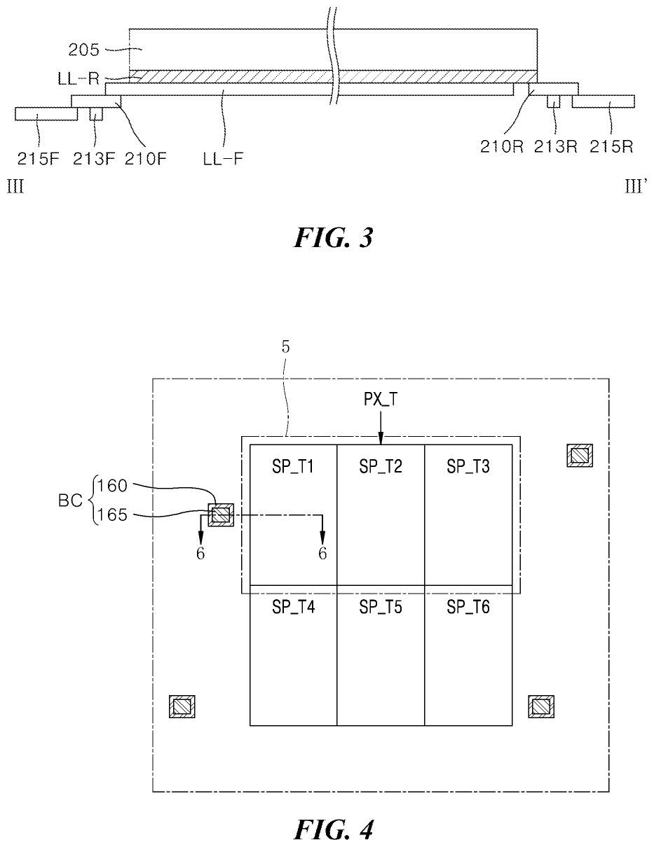

FIG. 1 is a schematic plan view of a display device according to an embodiment of the present disclosure. FIG. 2 is a schematic plan view of a wiring substrate according to one embodiment of the present disclosure. FIG. 3 is a cross-sectional view of lines III-III′ in FIG. 2.

In FIG. 1, for convenience of illustration, among components of a display device TD, only a wiring substrate 205, a plurality of link wiring lines LL, a plurality of circuit films 210F and 210R on which a plurality of integrated circuit chips 213F and 213R are respectively disposed, printed circuit boards 215F and 215R, and a plurality of display units TU are shown. FIG. 2 shows components of the wiring substrate 205 except for the plurality of display units TU among the components shown in FIG. 1.

Referring to FIGS. 1 to 3, the tiling display device TD according to one embodiment of the present disclosure may include the wiring substrate 205, and the plurality of display units TU arranged so as to be spaced apart from each other while being disposed on the wiring substrate 205. The display units TU may be arranged along each of a first direction and a second direction transverse to the first direction. In this regard, the first direction may be a horizontal direction (e.g., X-axis direction), and the second direction may be a vertical direction (e.g., Y-axis direction). The wiring substrate 205 may be composed of a single substrate and may include glass or transparent plastic.

The plurality of link wiring lines LL may be disposed on the wiring substrate 205. The plurality of link wiring lines LL may extend along one direction of the wiring substrate 205. The plurality of link wiring lines LL may include a first link wiring line LL-F carrying a first signal and a second link wiring line LL-R carrying a second signal different from the first signal. Depending on how the display device TD is oriented, the plurality of link wiring lines LL may be disposed below the wiring substrate 205 as you can see from the cross-section in FIG. 3. For example, the second link wiring line LL-R is disposed below the wiring substrate 205 and the first link wiring line LL-F is disposed below the second link wiring line LL-R.

A driver may be disposed on each of both opposing side ends of the wiring substrate 205. The driver may include each of the printed circuit boards 215F and 215R connected to each of the circuit films 210F and 210R on which each of the integrated circuit chips 213F and 213R is mounted. Each of the circuit films 210F and 210R is connected to each of ends of the link wiring lines LL-F and LL-R. The driver may transmit various signals to sub-pixels of each display unit TU. For example, the signals transmitted to the sub-pixels may include a high-potential voltage, a low-potential voltage, a scan signal, or a data signal. In an embodiment of the present disclosure, a configuration in which each driver including each of the printed circuit boards 215F and 215R connected to each of the circuit films 210F and 210R on which each of the integrated circuit chips 213F and 213R is mounted is disposed at each of both opposing side ends of the wiring substrate 205 is illustrated. However, the present disclosure is not limited thereto.

One of the plurality of drivers may include the first circuit film 210F disposed on one side end of the wiring substrate 205, and connected to the first link wiring line LL-F, and the first printed circuit board 215F connected to the first circuit film 210F. The first integrated circuit chip 213F is mounted on the first circuit film 210F. The other of the plurality of drivers may include the second circuit film 210R disposed on the other side end of the wiring substrate 205, and connected to the second link wiring line LL-R, and the second printed circuit board 215R connected to the second circuit film 210R. The second integrated circuit chip 213R is mounted on the second circuit film 210R.

Each of the plurality of display units TU disposed on the wiring substrate 205 may be connected to the wiring substrate 205 via an electrical connection between each of a plurality of signal lines and the second link wiring line LL-R disposed in the wiring substrate 205. The plurality of link wiring lines LL-F and LL-R may be disposed to overlap the plurality of display units TU, respectively, and may not be exposed to the outside. As a result, an area size of the circuit area in which the plurality of link wiring lines LL-F and LL-R are disposed may be reduced and thus the display area may be increased.

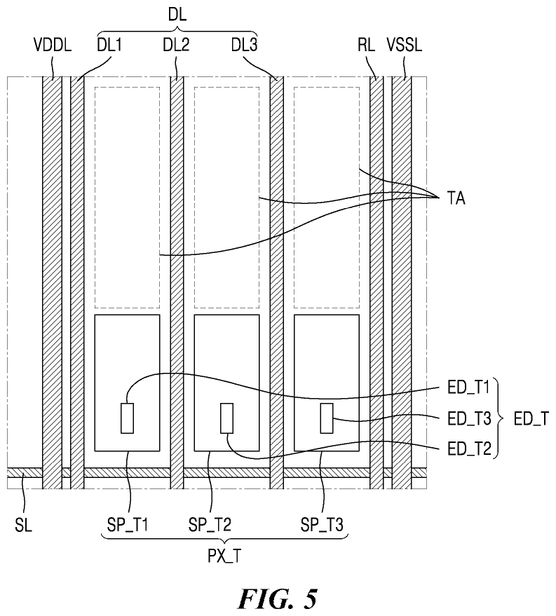

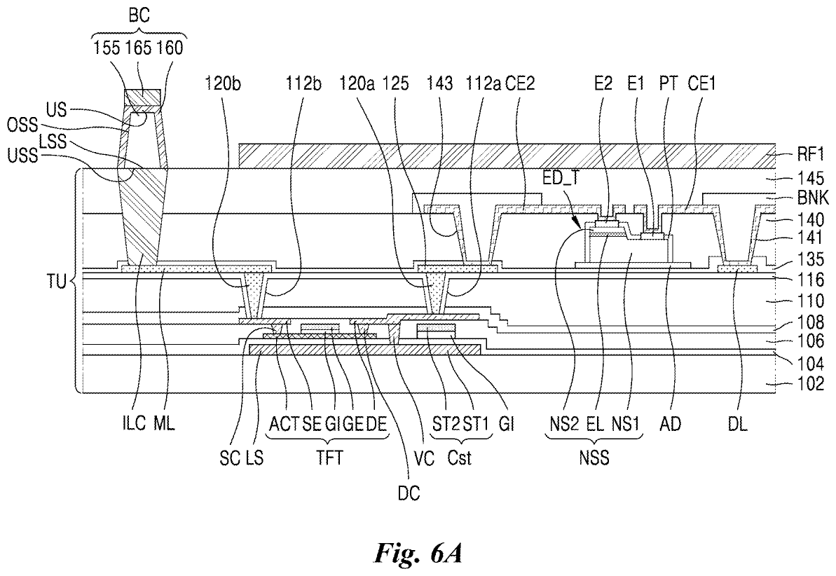

A plurality of pixels may be disposed on the wiring substrate 205, while a plurality of pixels may be disposed in each of the plurality of display units TU. A light-emitting element and a driving circuit including a thin-film transistor for driving the light-emitting element may be disposed in each of the plurality of pixels disposed in the display unit TU. However, only the light-emitting element may be disposed in each of the plurality of pixels disposed on the wiring substrate 205, while the thin-film transistor may not be disposed in each of the plurality of pixels disposed on the wiring substrate 205. This will be described with reference to FIG. 4 and FIG. 5 below.

FIG. 4 is a schematic enlarged plan view of 4 of FIG. 1 of the display device according to one embodiment of the present disclosure. FIG. 5 is a schematic enlarged plan view of 5 in FIG. 4. FIG. 4 is an enlarged plan view of a portion of an area corresponding to a pixel disposed in a display unit.

Referring to FIG. 4 and FIG. 5 together with FIG. 1, a plurality of pixels PX_T may be disposed in the display unit TU. The plurality of pixels PX_T may include a plurality of sub-pixels SP_T1, SP_T2, and SP_T3 arranged in a first row and a plurality of sub-pixels SP_T4, SP_T5, and SP_T6 arranged in a second row. The plurality of sub-pixels SP_T4, SP_T5, and SP_T6 arranged in the second row may be respectively located at lower ends of the plurality of sub-pixels SP_T1, SP_T2, and SP_T3 arranged in the first row. However, the present disclosure is not limited thereto. The plurality of sub-pixels SP_T1, SP_T2, and SP_T3 arranged in the first row may include the first sub-pixel SP_T1, the second sub-pixel SP_T2, and the third sub-pixel SP_T3, while the plurality of sub-pixels SP_T4, SP_T5, and SP_T6 arranged in the second row may include the fourth sub-pixel SP_T4, the fifth sub-pixel SP_T5, and the sixth sub-pixel SP_T6.

Each of the plurality of sub-pixels SP_T1, SP_T2, and SP_T3 arranged in the first row and the plurality of sub-pixels SP_T4, SP_T5, and SP_T6 arranged in the second row may include a light-emitting area and a circuit area for driving the light-emitting area. Hereinafter, with reference to FIG. 5, the plurality of sub-pixels SP_T1, SP_T2, and SP_T3 arranged in the first row will be described. Each of the plurality of sub-pixels arranged in the second row may include the same components as those of each of the plurality of sub-pixels arranged in the first row.

The light-emitting area may include a first light-emitting element ED_T1, a second light-emitting element ED_T2, and a third light-emitting element ED_T3 emitting light of different colors of red (R), green (G), and blue (B), respectively. The light-emitting area may refer to an area in which light emitted from the first to third light-emitting elements ED_T1, ED_T2, and ED T3 may be emitted to the outside. The light-emitting area may further include a white light-emitting element emitting white light. A light-emitting element according to an embodiment of the present disclosure may be embodied as a micro-LED (a Micro Light Emitting Diode). The micro-LED may be a LED made of an inorganic material, and may refer to a light-emitting element with a thickness of 100 μm or smaller or free of a growth substrate for growing the LED.

Each of a plurality of transmissive areas TA may be defined in each of the plurality of pixels. The transmissive area TA may be an area in which a non-transparent material or a reflective material is not disposed. That is, the transmissive area TA may not overlap with any of the non-transparent materials or reflective materials within the transparent display device so that the device properly functions as a transparent device (see FIG. 5). The transmissive area TA passes through external light. Therefore, a user viewing the transparent display device including the micro-LEDs may see through the transparent display device. The tiling display device TD according to an embodiment of the present disclosure (which can be in the form of a transparent display device) may secure transmittance due to the transmissive area TA. Thus, the tiling display device TD may be a transparent display device through which an object disposed of rear of the tiling display device TD (refer to FIG. 1) can be recognized by a viewer in front of the device.

A plurality of signal lines may be disposed on the display unit. The plurality of signal lines may include a high-potential voltage line VDDL, a low-potential voltage line VSSL, a reference voltage line RL, a data line DL, and a scan line SL.

The signal lines including the high-potential voltage line VDDL, the low-potential voltage line VSSL, the reference voltage line RL, the data line DL, and the scan line SL may be connected to a plurality of light-emitting elements disposed on the wiring substrate 205 via electrical connections thereof to the plurality of link wiring lines LL-F and LL-R disposed in the wiring substrate 205, respectively. This configuration will be described later with reference to the drawings.

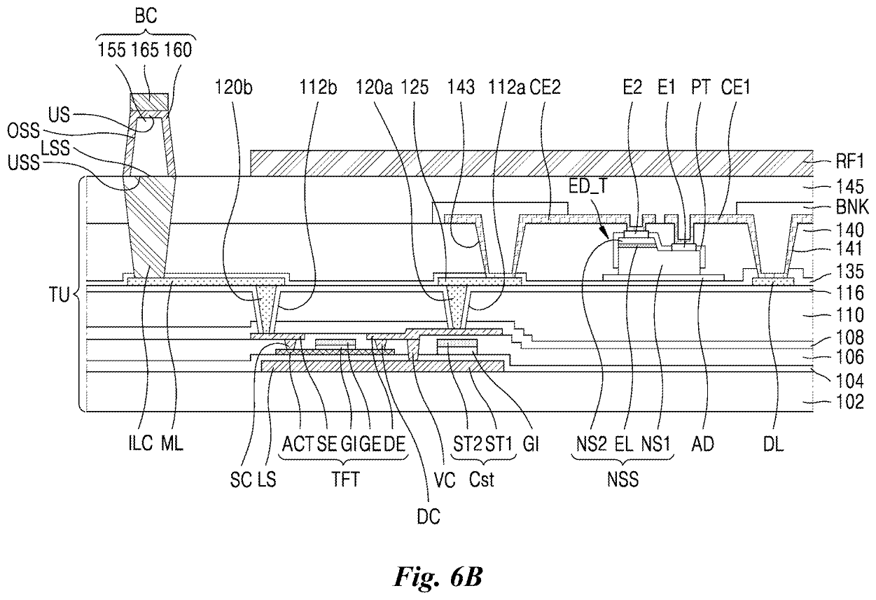

FIG. 6A is a cross-sectional view of 6 in FIG. 4. FIG. 6A shows one sub-pixel. A plurality of sub-pixels disposed in the display unit or on the wiring substrate may include the same components. FIG. 6B and FIG. 6A is identical except for the fact that the protective layer pattern PL does not contact the adhesive layer AD.

Referring to FIG. 6A, the sub-pixel SP_T1 disposed in the display unit TU may include a base substrate 102, and a thin-film transistor TFT, a storage capacitor Cst, and various lines disposed on the base substrate 102. The thin-film transistor TFT may drive the light-emitting element ED, and the storage capacitor Cst may store a voltage therein so that the light-emitting element ED continues to maintain the same state during one frame. The base substrate 102 may be made of a transparent material including glass or plastic.

A light-blocking layer LS may be disposed on the base substrate 102. The light-blocking layer LS may prevent light incident from the base substrate 102 from invading an active layer ACT of the thin-film transistor TFT to reduce leakage current. For example, the light-blocking layer LS may be disposed under the active layer ACT of the thin-film transistor TFT functioning as a driving transistor so as to prevent light from being incident to the active layer ACT.

A buffer layer 104 is disposed on the light-blocking layer LS. The buffer layer 104 may block impurities or moisture flowing through the base substrate 102. The buffer layer 104 may include, for example, an insulating material such as silicon oxide (SiOx) or silicon nitride (SiNx).

The thin-film transistor TFT is disposed on the buffer layer 104. The thin-film transistor TFT may include the semiconductor layer ACT, a gate electrode GE, a source electrode SE, and a drain electrode DE. A gate insulating layer GI may be disposed between the semiconductor layer ACT and the gate electrode GE.

The semiconductor layer ACT may include an active area overlapping the gate electrode GE to constitute a channel, and a source area and a drain area located respectively on both opposing sides of the active area disposed therebetween. An interlayer insulating film 106 is disposed on the gate electrode GE. The interlayer insulating film 106 may receive a source contact SC and a drain contact DC therein. The source contact SC and the drain contact DC may contact portions of surfaces of the source area and the drain area of the semiconductor layer ACT, respectively. The source contact SC and the drain contact DC may be respectively electrically connected to the source electrode SE and the drain electrode DE located on the interlayer insulating film 106. Thus, the source electrode SE and the drain electrode DE may be respectively electrically connected to the source and drain areas of the semiconductor layer ACT via the source contact SC and the drain contact DC. Each of the source electrode SE and the drain electrode DE may be made of a conductive material such as copper (Cu), aluminum (Al), molybdenum (Mo), nickel (Ni), titanium (Ti), chromium (Cr), or an alloy thereof. However, the present disclosure is not limited thereto.

The storage capacitor Cst may include a first capacitor electrode ST1 and a second capacitor electrode ST2. The first capacitor electrode ST1 may be disposed between the base substrate 102 and the buffer layer 104. The first capacitor electrode ST1 may be formed integrally with the light-blocking layer LS. The buffer layer 104 and the gate insulating layer GI may be disposed on the first capacitor electrode ST1 and may act as a dielectric layer. The second capacitor electrode ST2 may be disposed on the gate insulating layer GI. The second capacitor electrode ST2 may be made of the same material as that of the gate electrode GE.

A first passivation layer 108 is disposed on the source electrode SE and the drain electrode DE. The first passivation layer 108 serves to protect the thin-film transistor TFT and may include an insulating material. A first planarization layer 110 is disposed on the first passivation layer 108. The first planarization layer 110 serves to remove a surface step caused by an underlying component such as the thin-film transistor TFT. The first planarization layer 110 may include a photoactive compound (PAC). However, the present disclosure is not limited thereto.

The first planarization layer 110 may have contact-holes 112a and 112b defined therein respectively exposing portions of surfaces of the source electrode SE and drain electrode DE. Via contacts 120a and 120b may respectively fill the contact-holes 112a and 112b. The contact-holes 112a and 112b may include the first contact-hole 112a exposing a portion of the surface of the drain electrode DE and the second contact-hole 112b exposing a portion of the surface of the source electrode SE. The via contacts 120a and 120b may include the first via contact 120a filling the first contact-hole 112a and the second via contact 120b filling the second contact-hole 112b.

A connection electrode 125 connected to the first via contact 120a and a line electrode ML connected to the second via contact 120b may be disposed on the second passivation layer 116. The drain electrode DE connected to the first via contact 120a may be electrically connected to the light-blocking layer LS via a through-electrode VC extending through the interlayer insulating film 106 and the buffer layer 104.

The connection electrode 125, the signal line DL and the line electrode ML may be disposed in the same plane. A third passivation layer 135 may not cover a portion of a top surfaces of each of the connection electrode 125, the data line DL, and the line electrode ML so as to be exposed.

The light-emitting element ED_T may be disposed on the third passivation layer 135 and may be fixed thereto via an adhesive layer AD. The light-emitting element ED_T may be covered with a second planarization layer 140 having a first opening 141 and a second opening 143 defined therein. A first electrode E1 and a second electrode E2 of the light-emitting element ED_T may be electrically connected to a first line electrode CE1 and a second line electrode CE2, respectively. The first line electrode CE1 may be electrically connected to the data line DL. The second line electrode CE2 may be electrically connected to the drain electrode DE via the connection electrode 125.

The first opening 141 and the second opening 143 may be filled with a material constituting a bank BNK. A sealing layer 145 may be disposed on the second planarization layer 140 receiving therein the bank BNK.

An interlayer connection electrode ILC may extend through the sealing layer 145 and the second planarization layer 140 and may contact the exposed portion of the top surface of the line electrode ML. The interlayer connection electrode ILC may be electrically connected to the thin-film transistor TFT of the display unit TU via the line electrode ML.

A bonding member BC may be disposed on the interlayer connection electrode ILC. The bonding member BC may include a spacer pattern 155, a conductive connection pattern 160, and an adhesive pattern 165. A lower surface LSS of the spacer pattern 155 may be in contact with an upper surface USS of the interlayer connection electrode ILC. The spacer pattern 155 may play a role of maintaining a gap between the wiring substrate and the display unit TU. The spacer pattern 155 may have a taper shape in which a width of the lower surface LSS that is in contact with the interlayer connection electrode ILC is larger than that of the upper surface US of the spacer pattern 155. Accordingly, as shown in FIG. 6A, the spacer pattern 155 may have a trapezoid-shaped cross-section. However, the present disclosure is not limited thereto.

An outer side surface OSS of the spacer pattern 155 may be covered with the conductive connection pattern 160. For example, the conductive connection pattern 160 may cover the upper surface US of the spacer pattern 155 and surround the outer side surface OSS thereof. Further, the conductive connection pattern 160 may contact the upper surface USS of the interlayer connection electrode ILC. The conductive connection pattern 160 may include, but is not limited to, a conductive material such as copper (Cu), aluminum (Al), molybdenum (Mo), nickel (Ni), titanium (Ti), chromium (Cr), or an alloy thereof.

The adhesive pattern 165 may be disposed on a portion of the conductive connection pattern 160 covering the upper surface of the spacer pattern 155. The adhesive pattern 165 may bond and fix the wiring substrate 205 and the display unit TU to each other.

Further, the adhesive pattern 165 may have electrical conductivity to transmit a driving signal from the thin-film transistor TFT of the display unit TU to the light-emitting element disposed on the wiring substrate 205 such that the light-emitting element on the wiring substrate 205 emits light. Accordingly, in some embodiments, the adhesive pattern 165 may include a material having electrical conductivity and adhesiveness.

In one example, in a transparent display device in which a light-emitting element is disposed only in the display unit, when the viewer facing an opposite surface to a display surface from which the image is outputted views the transparent display device, the viewer may view a reversed image of the image from the display surface. This may limit the use of the transparent display device. Further, there is a problem in that visibility is deteriorated due to occurrence of a mura phenomenon.

However, in an embodiment of the present disclosure, different signals may be respectively transmitted to both opposing surfaces of one display device so as to output different images respectively on the both opposing surfaces of the display device. For example, the light-emitting element may be disposed on the wiring substrate 205. Thus, the light may be emitted not only from the display unit TU but also from the wiring substrate 205, such that different images may be respectively output from both opposing surfaces of the display device. This will be described with reference to the drawings below.

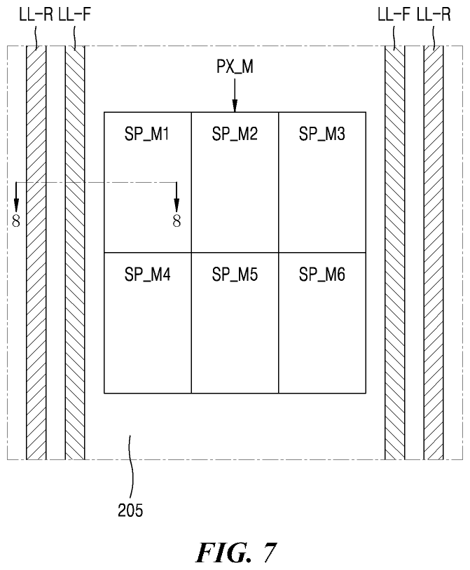

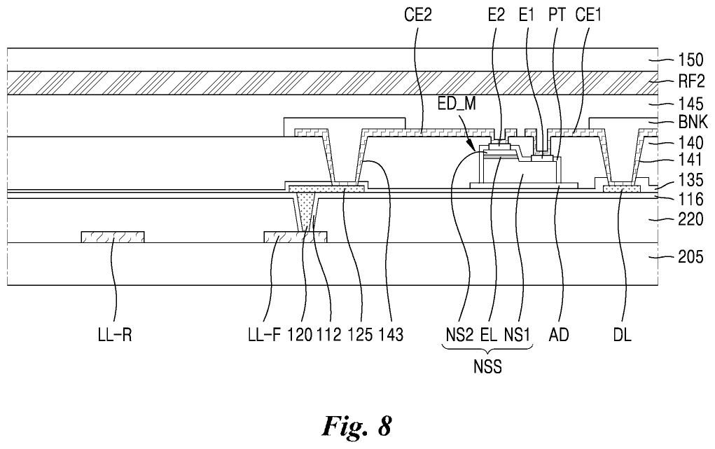

FIG. 7 is a schematic enlarged plan view of 7 of FIG. 2 of the display device according to one embodiment of the present disclosure. FIG. 8 is a cross-sectional view of 8 in FIG. 7. A light-emitting element ED_M in FIG. 8 includes the same components as those of the light-emitting element ED_T in FIG. 6A. The same components may be briefly described or description thereof may be omitted.

Referring to FIG. 7 and FIG. 8 together with FIG. 2, a plurality of first link wiring lines LL-F and a plurality of second link wiring lines LL-R may be disposed on the wiring substrate 205. The first link wiring line LL-F and the second link wiring line LL-R may be spaced apart from each other and may transmit different signals. For example, a first signal may be delivered via the first link wiring line LL-F, and a second signal different from the first signal may be delivered via the second link wiring line LL-R.

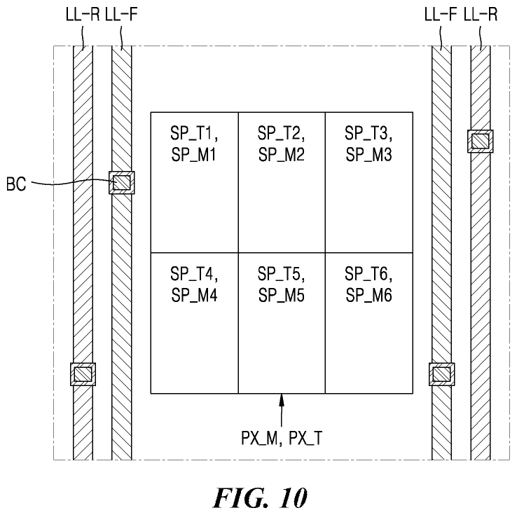

Accordingly, in some embodiments, the first signal may be transferred from the first printed circuit board 215F disposed at one side of the display device TD to the first link wiring line LL-F. The second signal different from the first signal may be transmitted from the second printed circuit board 215R disposed at the other side opposite to one side of the display device TD to the second link wiring line LL-R. Although FIG. 1 illustrates as if the first link wiring line LL-F is disposed on the left side (seen from the figure) and the second link wiring line LL-R is disposed on the right side of LL-F, the embodiment is not limited to this arrangement. For example, the first link wiring lines LL-F and the second link wiring lines LL-R may be alternately arranged with each other. This arrangement of the first link wiring lines LL-F and the second link wiring lines LL-R is shown in FIGS. 7 and 10. However, the present disclosure is not limited thereto.

A pixel PX_M may be disposed on the wiring substrate 205. A plurality of pixels PX_M may include a plurality of sub-pixels SP_M1, SP_M2, and SP_M3 arranged in a first row and a plurality of sub-pixels SP_M4, SP_M5, and SP_M6 arranged in a second row. The plurality of sub-pixels SP_M4, SP_M5, and SP_M6 arranged in the second row may be respectively located at lower ends of the plurality of sub-pixels SP_M1, SP_M2, and SP_M3 arranged in the first row. However, the present disclosure is not limited thereto. The plurality of sub-pixels SP_M1, SP_M2, and SP_M3 arranged in the first row may include the first sub-pixel SP_M1, the second sub-pixel SP_M2, and the third sub-pixel SP_M3, while the plurality of sub-pixels SP_M4, SP_M5, and SP_M6 arranged in the second row may include the fourth sub-pixel SP_M4, the fifth sub-pixel SP_M5, and the sixth sub-pixel SP_M6.

Each of the plurality of sub-pixels SP_M1, SP_M2, and SP_M3 arranged in the first row and the plurality of sub-pixels SP_M4, SP_M5, and SP_M6 arranged in the second row include a light-emitting area and a circuit area for driving the light-emitting area. Hereinafter, referring to FIG. 5, the plurality of sub-pixels SP_M1, SP_M2, and SP_M3 arranged in the first row will be described. Each of the plurality of sub-pixels arranged in the second row may include the same components as each of the plurality of sub-pixels arranged in the first row.

Referring to FIG. 8, a first buffer layer 220 may be disposed on the first link wiring line LL-F and the second link wiring line LL-R. The first buffer layer 220 may have a contact-hole 112 defined therein. The contact-hole 112 may expose a portion of a surface of the first buffer layer 220. The second passivation layer 116 including an insulating material may be disposed on the first buffer layer 220. A via contact 120 may fill the contact-hole 112. The connection electrode 125 connected to the via contact 120 may be disposed on the second passivation layer 116. One surface of the via contact 120 may be connected to the first link wiring line LL-F and the other surface thereof may be connected to the connection electrode 125.

The signal line may be disposed on the second passivation layer 116. According to one embodiment, the signal line may be coplanar with the connection electrode 125. According to other embodiments, the signal line may be disposed on the second passivation layer 116 and be on the same layer as the connection electrode 125. The signal line although used as singular here may also include a plurality of signal lines. For example, the plurality of signal lines may include a plurality of scan lines SL, a plurality of high-potential power lines VDDL, a plurality of data lines DL, and a plurality of reference voltage lines RL. In an embodiment of the present disclosure, the data line DL is shown for convenience of illustration. However, the present disclosure is not limited thereto. The plurality of signal lines may be disposed on the same plane. Further, the plurality of signal lines may be made of the same material as that of the connection electrode 125.

The third passivation layer 135 covering the connection electrode 125, the data line DL, and the second passivation layer 116 is disposed. The third passivation layer 135 may not cover a portion of the upper surface of each of the connection electrode 125 and the data line DL so as to be exposed.

A light-emitting element ED_M may be disposed on and fixed to the adhesive layer AD disposed on the third passivation layer 135. The light-emitting element ED_M may include a nitride semiconductor structure NSS, a first electrode E1 and a second electrode E2. The nitride semiconductor structure NSS may include a first semiconductor layer NS1, a light-emitting layer EL disposed on one side of the first semiconductor layer NS1, and the second semiconductor layer NS2 disposed on the light-emitting layer EL. The first electrode E1 is disposed on the other side of the first semiconductor layer NS1 where the light-emitting layer EL is not located, and the second electrode E2 is disposed on the second semiconductor layer NS2. A protective layer pattern PT may cover an outer side surface of the light-emitting element ED. In some embodiments, the light-emitting layer EL includes an inorganic material. In some embodiments, the light-emitting layer EL is made of an inorganic material.

The light-emitting element ED_M may be covered with the second planarization layer 140. The second planarization layer 140 may have a thickness sufficient to planarize a stepped upper surface resulting from an underlying circuit element. The second planarization layer 140 may have openings 141 and 143 defined therein. The openings 141 and 143 may include the first opening 141 and the second opening 143. Further, the second planarization layer 140 may not cover a portion of an upper surface of each of the first electrode E1 and the second electrode E2 of the light-emitting element ED so as to be exposed. The first electrode E1 and the second electrode E2 may be electrically connected to the first line electrode CE1 and the second line electrode CE2, respectively.

The first line electrode CE1 may extend along and on an exposed surface of the first opening 141, and the second line electrode CE2 may extend along and on an exposed surface of the second opening 143. The first line electrode CE1 may be electrically connected to the data line DL. The second line electrode CE2 may be electrically connected to the first link wiring line LL-F of the wiring substrate 205 via the connection electrode 125. Further, the second link wiring line LL-R may be electrically connected to the thin-film transistor TFT of the display unit TU.

The bank BNK may be disposed on the second planarization layer 140. The bank BNK may include an opaque material. However, the present disclosure is not limited thereto. In one example, the bank BNK may be formed to cover the first line electrode CE1 and the second line electrode CE21. The first opening 141 and the second opening 143 may be filled with the material constituting the bank BNK. Further, the bank BNK may be disposed in an area around the light-emitting element ED_M excluding the area where the light-emitting element ED_M is disposed.

The sealing layer 145 may be disposed on the second planarization layer 140 and the bank BNK. A second reflective electrode RF2 may be disposed on the sealing layer 145. The second reflective electrode RF2 may include a metal material with high reflectivity. For example, the metal material with high reflectivity may have a single-layer structure or a stack structure made of any one material selected from aluminum (Al), copper (Cu), silver (Ag), molybdenum (Mo), gold (Au), magnesium (Mg), calcium (Ca), or barium (Ba), or an alloy of at least two thereof.

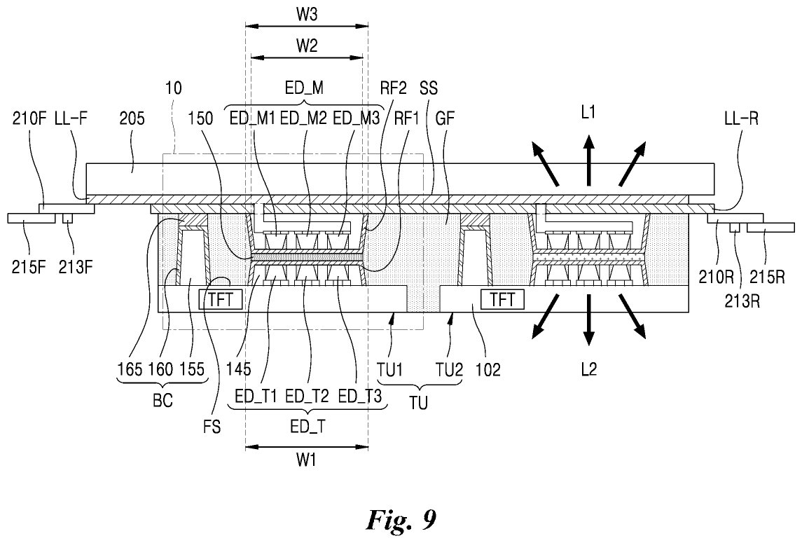

Different signals may be respectively inputted to the light-emitting elements ED_M and ED_T respectively disposed on the wiring substrate 205 and each of the plurality of display units TU bonded to the wiring substrate 205, such that different images may be respectively output in different directions from the wiring substrate 205 and the display unit TU. This will be described with reference to FIG. 9 and FIG. 10 below.

FIG. 9 is a schematic cross-sectional view of 9 in FIG. 1. FIG. 10 is a schematic enlarged plan view of 10 in FIG. 9.

Referring to FIGS. 9 and 10, each of the display units TU1 and TU2 on which the light-emitting element ED_T is disposed may be disposed on and bonded to the wiring substrate 205 on which the light-emitting element ED_M different from the light-emitting element ED_T is disposed. More specifically, the base substrate 102 has a first surface FS and the wiring substrate 205 opposite the base substrate 102, has a second surface SS. As shown in FIG. 9, the second surface SS of the wiring substrate 205 and the first surface FS of the base substrate 102 faces each other. The light-emitting element ED_T is disposed on the first surface FS of the base substrate 102 and the light-emitting element ED_M is disposed on the second surface SS of the wiring substrate 205. According to one embodiment, at least one of the first light-emitting element ED_T1, the second light-emitting element ED_T2, and the third light-emitting element ED_T3 of the light-emitting element ED_T at least partially overlap with at least one of the first light-emitting element ED_M1, the second light-emitting element ED_M2, and the third light-emitting element ED_M3 of the light-emitting element ED_M. According to another embodiment, the light-emitting element ED_M and the light-emitting element ED_T fully overlaps with each other such that the first light-emitting element ED_T1, the second light-emitting element ED_T2, and the third light-emitting element ED_T3 fully overlap with the first light-emitting element ED_M1, the second light-emitting element ED_M2, and the third light-emitting element ED_M3, respectively.

The display unit TU may include the first display unit TU1 and the second display unit TU2 arranged and adjacent to each other in one direction. Further, as shown, the first display unit TU1 and the second display unit TU2 are spaced apart from each other. In the drawing, only a configuration in which two display units TU1 and TU2 are arranged is presented for convenience of illustration. However, the present disclosure is not limited thereto. For example, further display unit may be disposed adjacent to one side of each display unit.

In FIG. 9, a width W1 of the first reflective electrode RF1, a width W3 of the second reflective electrode RF2, a width W2 of a reflective bonding layer 150. In one embodiment, the width W1 of the first reflective electrode RF1 and the width W3 of the second reflective electrode RF2 are substantially the same. Further, the width W2 of a reflective bonding layer 150 is smaller than either the width W1 of the first reflective electrode RF1 or the width W3 of the second reflective electrode RF2.

The first link wiring line LL-R and the second link wiring line LL-F are disposed on the wiring substrate 205. The display units TU1 and TU2 may be disposed on and bonded to the wiring substrate 205 via the bonding members BC, while the bonding members BC disposed on the display units TU1 and TU2, respectively may overlap the first link wiring line LL-R and the second link wiring line LL-F, respectively. Further, each of the display units TU1 and TU2 on which the light-emitting element ED_T is disposed may be bonded to the wiring substrate 205 on which the light-emitting element ED_M different from the light-emitting element ED_T is disposed via a reflective bonding layer 150. For example, the reflective bonding layer 150 may include silver paste (Ag paste).

Accordingly, as shown in FIG. 10, the plurality of sub-pixels SP_M1, SP_M2, and SP_M3 arranged in the first row of the pixel PX_M of the wiring substrate 205 may vertically face and overlap respectively and positionally correspond to the plurality of sub-pixels SP_T1, SP_T2, and SP_T3 arranged in the first row of the display unit TU. Further, the plurality of sub-pixels SP_M4, SP_M5, and SP_M6 arranged in the second row of the pixel PX_M of the wiring substrate 205 may vertically face and overlap respectively and positionally correspond to the plurality of sub-pixels SP_T4, SP_T5, and SP_T6 arranged in the second row of the display unit TU.

Therefore, the pixel PX_M of the wiring substrate 205 and the pixel PX_T of the display unit TU may overlap each other as seen from a plan view. In this regard, the bonding members BC may be respectively disposed on the first link wiring line LL_F and the second link wiring line LL-R so as to electrically connect the wiring substrate 205 to the display unit TU.

A sub-pixel equipped with the light-emitting element ED_T and the thin-film transistor TFT for driving the light-emitting element ED_T may be disposed in each of the first display unit TU1 and the second display unit TU2. The light-emitting element ED_T disposed in each of the display units TU1 and TU2 may include the first light-emitting element ED_T1, the second light-emitting element ED_T2, and the third light-emitting element ED_T3. The first light-emitting element ED_T1, the second light-emitting element ED_T2, and the third light-emitting element ED_T3 may respectively emit light of different colors.

The light emitted from the light-emitting element ED_T of the display unit TU may be emitted toward an open area defined by the bank BNK, and then may be emitted toward the wiring substrate 205. In this regard, the first reflective electrode RF1 disposed on the light-emitting element ED_T of the display unit TU reflects the light emitted from the light-emitting element ED_T of the display unit TU therefrom so as to be directed toward the base substrate 102 of the display unit TU, such that light L2 emits to the outside.

Further, the light emitted from the light-emitting element ED_M disposed on the wiring substrate 205 may be emitted toward the display units TU1 and TU2. In this regard, the second reflective electrode RF2 disposed on the light-emitting element ED_M of the wiring substrate 205 reflects light emitted from the light-emitting element ED_M of the wiring substrate 205 therefrom so as to be directed to the wiring substrate 205 such that light L1 emits to the outside.

A space between the wiring substrate 205 and the display unit TU may be filled with a refractive index matching layer GF made of a transparent material. For example, the refractive index matching layer GF may be a material having the same refractive index as that of glass. Accordingly, a boundary area between adjacent display units TU1 and TU2 may be prevented from being visually recognized by a user, thereby improving transparency.

Therefore, a display device in which a bezel area as a boundary area between adjacent display units TU1 and TU2 is implemented as a zero-bezel area in which a bezel area is substantially absent may be realized.

The wiring substrate 205 and the display units TU1 and TU2 may be electrically connected to each other via the bonding members BC. The light-emitting element ED_M disposed on the wiring substrate 205 may receive the first signal input from the first printed circuit board 215F opposite to the second printed circuit board 215R via the first link wiring line LL-F such that the light-emitting element ED_M disposed on the wiring substrate 205 may output a first image onto a surface of the wiring substrate 205 where the link wiring line LL is not disposed. Further, the light-emitting element ED_T disposed in each of the display units TU1 and TU2 may receive the second signal input from the second printed circuit board 215R via the second link wiring line LL-R such that the light-emitting element ED_T disposed in each of the display units TU1 and TU2 may output a second image different from the first image through each of the display units TU1 and TU2 to the outside.

According to an embodiment of the present disclosure, the display device includes the wiring substrate on which the plurality of first link wiring lines transmitting the first signal and the plurality of second link wiring lines transmitting the second signal different from the first signal are disposed, wherein the plurality of first group of light-emitting elements are disposed on the wiring substrate; and the plurality of display units disposed on and bonded to the wiring substrate, wherein the plurality of display units are spaced apart from each other, wherein the plurality of second group of light-emitting elements different from the plurality of first group of light-emitting elements are disposed in each of the plurality of display units. The plurality of first group of light-emitting elements respectively overlap the plurality of second group of light-emitting elements. Thus, a large-area transparent display device may be realized.

Further, according to an embodiment of the present disclosure, the display device in which different signals are input into one display device such that different images are respectively outputted from both opposing surfaces of the display device to an outside out of the device may be provided.

Further, one thin-film transistor drives the light-emitting element disposed on the wiring substrate and the light-emitting element disposed in the display unit, thereby unifying parts with other and thus manufacturing the eco-friendly product.

Further, a refractive index matching layer may be disposed between adjacent display units to improve transparency. Thus, a display device in which a bezel area is minimum or substantially absent to realize a zero-bezel area may be realized.

A display device according to an embodiment of the present disclosure may be described as follows.

A display device includes a wiring substrate on which a plurality of first link wiring lines transmitting a first signal and a plurality of second link wiring lines transmitting a second signal different from the first signal are disposed, wherein a plurality of first group of light-emitting elements are disposed on the wiring substrate; a plurality of display units disposed on and bonded to the wiring substrate, wherein the plurality of display units are spaced apart from each other, wherein a plurality of second light-emitting elements different from the plurality of first group of light-emitting elements are disposed in each of the plurality of display units; a reflective bonding layer positioned between the wiring substrate and the plurality of display units; and a plurality of bonding members disposed between the display units and the wiring substrate, wherein the plurality of bonding members respectively overlap the plurality of the first link wiring lines and the plurality of the second link wiring lines.

According to some implementations of the present disclosure, the wiring substrate is composed of a single substrate, wherein the plurality of display units are disposed on the wiring substrate and are arranged so as to be spaced apart from each other in each of first and second horizontal directions intersecting each other.

According to some implementations of the present disclosure, the display device further includes a first circuit film disposed on one side end of the wiring substrate and connected to the first link wiring line, wherein a first integrated circuit chip for transmitting the first signal to the plurality of first group of light-emitting elements disposed on the wiring substrate is disposed on the first circuit film; a first printed circuit board connected to the first circuit film; a second circuit film disposed on the other side end opposite to the one side end of the wiring substrate, and connected to the second link wiring line, wherein a second integrated circuit chip for transmitting the second signal to the plurality of second light-emitting elements of the display unit is disposed on the second circuit film; and a second printed circuit board connected to the second circuit film.

According to some implementations of the present disclosure, the plurality of first group of light-emitting elements disposed on the wiring substrate receive the first signal and output a first image through an outer surface of the wiring substrate to an outside, wherein the plurality of second light-emitting elements of the display unit receive the second signal and output a second image different from the first image through an outer surface of the display unit to the outside.

According to some implementations of the present disclosure, each of the display units further includes: a sealing layer covering the second group of light-emitting elements and constituting an uppermost layer of each of the display units; and a first reflective electrode disposed on the sealing layer.

According to some implementations of the present disclosure, the wiring substrate further includes: a sealing layer covering the first group of light-emitting elements and constituting an uppermost layer of the wiring substrate; and a second reflective electrode disposed on the sealing layer.

According to some implementations of the present disclosure, the first reflective electrode and the second reflective electrode are positioned so as to face each other.

According to some implementations of the present disclosure, the reflective bonding layer includes silver (Ag) paste.

According to some implementations of the present disclosure, the display device further includes a refractive index matching layer disposed between the wiring substrate and the plurality of display units, wherein the refractive index matching layer includes a material having a refractive index substantially equal to a refractive index of glass, wherein the refractive index matching layer is disposed in a boundary area between adjacent ones of the plurality of display units.

According to some implementations of the present disclosure, each of the display units includes: a base substrate; a light-blocking layer disposed on the base substrate; a thin-film transistor disposed on the light-blocking layer and including a semiconductor layer, a gate electrode, a source electrode and a drain electrode; a first planarization layer covering the thin-film transistor disposed on the base substrate, wherein a first via contact connected to the drain electrode and a second via contact connected to the source electrode extend through the first planarization layer; a line electrode electrically connected to the second via contact; and a second planarization layer through which an interlayer connection electrode connected to the line electrode extends, wherein one surface of the interlayer connection electrode is connected to each bonding member.

According to some implementations of the present disclosure, the thin-film transistor transmits a driving signal to the first group of light-emitting element disposed on the wiring substrate and/or the second group of light-emitting element of the display unit.

According to some implementations of the present disclosure, each bonding member includes: a spacer pattern having one surface contacting the wiring substrate; a conductive connection pattern covering an upper surface and an outer side surface of the spacer pattern; and an adhesive pattern disposed on the conductive connection pattern, wherein one surface of the adhesive pattern contacts each second link wiring line on the wiring substrate.

A display device according to some embodiments of the present disclosure may also include the following display device and transparent display device.

For instance, a display device includes a base substrate 102 having a first surface FS and a wiring substrate 205 having a second surface SS. The second surface SS of the wiring substrate 205 faces the first surface FS of the base substrate 102. The display device includes a plurality of light-emitting elements ED_M and ED_T including first light-emitting elements (e.g., ED_T1, ED_T2, ED_T3) and second light-emitting elements (e.g., ED_M1, ED_M2, ED_M3). The first light-emitting elements are disposed on the first surface FS of the base substrate 102 and the second light-emitting elements disposed on the second surface SS of the wiring substrate 205.

The display device includes a first reflective electrode RF1 covering the first light-emitting elements ED_T and a second reflective electrode RF2 covering the second light-emitting elements ED_M. In some embodiments, the first light-emitting elements and the second light-emitting elements partially overlap each other from a plan view.

The display device further includes a reflective bonding layer 150 between the first reflective electrode RF1 and the second reflective electrode RF2, and the first reflective electrode and the second reflective electrode face each other. In some embodiments, the reflective bonding layer directly contacts both the first reflective electrode and the second reflective electrode.

In some embodiments, a width W3 of the reflective bonding layer in a first direction is smaller than a width W1 of the first reflective electrode or width W2 of the second reflective electrode in the first direction.

The display device further includes a bonding member adjacent to at least one of the first light-emitting elements or the second light-emitting elements and between the base substrate and the wiring substrate. The bonding member includes a spacer pattern, a conductive connection pattern on the spacer pattern, and an adhesive pattern on the conductive connection pattern. The bonding member, in operation, bonds the base substrate 102 to the wiring substrate 205.

The display device further includes a refractive index matching layer GF in a space between the bonding member and the first and second reflective electrodes. For instance, the refractive index matching layer GF includes a transparent material.

The display device further includes a first link wiring line and a second link wiring line. Here, the first link wiring line and the second link wiring line are adjacent to the first and second light-emitting elements. The bonding member may include one or more bonding members, each of the one or more bonding members respectively disposed on the first link wiring line and the second link wiring line to electrically connect the wiring substrate to the base substrate.

The display device further includes a first circuit film disposed on one side end of the wiring substrate and electrically connected to the first link wiring line. The device may also include a first integrated circuit chip for transmitting first signals to the first light-emitting elements disposed on the base substrate. Here, the first integrated circuit chip may be disposed on the first circuit film. The device may also include a first printed circuit board electrically connected to the first circuit film and a second circuit film disposed on the other side end opposite to the one side end of the wiring substrate, and electrically connected to the second link wiring lines.

The device may also include a second integrated circuit chip for transmitting second signals to the second light-emitting elements disposed on the wiring substrate. Here, the second integrated circuit chip is disposed on the second circuit film. The device may also include a second printed circuit board that is electrically connected to the second circuit film. In operation, the first light-emitting elements disposed on the base substrate receive first signals and output a first image in a direction opposite of the first reflective electrode and through the base substrate. Further, in operation, the second light-emitting elements disposed on the wiring substrate receive second signals and output a second image different from the first image in a direction opposite of the second reflective electrode and through the wiring substrate.

A display device according to some embodiments of the present disclosure may also include the following transparent display device (see FIGS. 5 and 6).

The transparent display device includes a plurality of subpixels on the first surface FS of the base substrate 102. Each subpixel includes a transmissive area TA and a display area adjacent to the transmissive area TA. Here, the display area includes a micro light emitting diode (micro-LED). The transmissive area TA is configured to transmit external light through the display device in order to provide a transparent display device. In some embodiments, the transmissive area TA does not overlap with either a non-transparent material or a reflective material of the display device from a plan view.

In some embodiments, the micro-LED includes a semiconductor structure, first electrode, and a second electrode. The semiconductor structure includes a first semiconductor layer, a second semiconductor layer, and a light-emitting layer made of an inorganic material. The light-emitting layer is between the first semiconductor layer and the second semiconductor layer.

The transparent display device includes an adhesive layer AD on the base substrate 102. The adhesive layer AD is located between the micro-LED ED_T (see FIG. 6AA) and the base substrate 102.

According to FIGS. 6A and 6B, the adhesive layer of the transparent display device is in direct contact with the first semiconductor layer NS1. For example, the adhesive layer AD, in operation, fixes the micro-LED ED_T to the adhesive layer AD.

In one or more embodiments, a protective layer pattern PT at least partially covers the micro-LED as shown in FIGS. 6A and 6B. For instance, the protective pattern PT contacts at least one of the first semiconductor layer NS1, the light-emitting layer EL, and the second semiconductor layer NS2. Here, the light-emitting layer EL includes an inorganic material.

In some embodiments, the protective pattern PT extends from either the first electrode E1 or the second electrode E2 and contacts at least one of the first semiconductor layer NS1, the light-emitting layer EL, and the second semiconductor layer NS2. In some embodiments, the first electrode E1 is between the second electrode E2 and the base substrate 102.

In some embodiments, as shown in FIG. 6B, the protective layer pattern PT is spaced apart from the adhesive layer AD. That is, as shown in FIG. 6B, the protective layer pattern PT may include a first protective layer pattern FPT that extends from the first electrode E1 and further extends toward the base substrate 102 and a second protective layer pattern SPT that extends from the second electrode E2 and further extends toward the base substrate 102.

Here, according to FIG. 6B, at least one of the first protective layer pattern FPT or the second protective layer pattern SPT is spaced apart from the adhesive layer AD.

Although the embodiments of the present disclosure have been described in more detail with reference to the accompanying drawings, the present disclosure is not necessarily limited to these embodiments, and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a base substrate having a first surface;
a wiring substrate having a second surface, the second surface of the wiring substrate facing the first surface of the base substrate;
a plurality of light-emitting elements including first light-emitting elements and second light-emitting elements, the first light-emitting elements disposed on the first surface of the base substrate and the second light-emitting elements disposed on the second surface of the wiring substrate;
a first reflective electrode covering the first light-emitting elements; and
a second reflective electrode covering the second light-emitting elements;
wherein the first light-emitting elements and the second light-emitting elements partially overlap each other from a plan view.

2. The display device of claim 1, comprising:
a reflective bonding layer between the first reflective electrode and the second reflective electrode.

3. The display device of claim 2, wherein the first reflective electrode and the second reflective electrode face each other, and
wherein the reflective bonding layer directly contacts both the first reflective electrode and the second reflective electrode.

4. The display device of claim 2, comprising:
wherein a width of the reflective bonding layer in a first direction is smaller than a width of the first reflective electrode or the second reflective electrode in the first direction.

5. The display device of claim 1, comprising:
a bonding member adjacent to at least one of the first light-emitting elements or the second light-emitting elements and between the base substrate and the wiring substrate, the bonding member including a spacer pattern, a conductive connection pattern on the spacer pattern, and an adhesive pattern on the conductive connection pattern,
wherein the bonding member, in operation, bonds the base substrate to the wiring substrate.

6. The display device of claim 5, comprising a refractive index matching layer in a space between the bonding member and the first and second reflective electrodes, the refractive index matching layer including a transparent material.

7. The display device of claim 6, comprising a first link wiring line and a second link wiring line, the first link wiring line and the second link wiring line being adjacent to the first and second light-emitting elements,
wherein the bonding member includes one or more bonding members, each of the one or more bonding members respectively disposed on the first link wiring line and the second link wiring line to electrically connect the wiring substrate to the base substrate.

8. The display device of claim 7, comprising:
a first circuit film disposed on one side end of the wiring substrate and electrically connected to the first link wiring line;
a first integrated circuit chip for transmitting first signals to the first light-emitting elements disposed on the base substrate, the first integrated circuit chip disposed on the first circuit film;
a first printed circuit board electrically connected to the first circuit film;
a second circuit film disposed on the other side end opposite to the one side end of the wiring substrate, and electrically connected to the second link wiring lines;
a second integrated circuit chip for transmitting second signals to the second light-emitting elements disposed on the wiring substrate, the second integrated circuit chip disposed on the second circuit film; and
a second printed circuit board electrically connected to the second circuit film.

9. The display device of claim 1, wherein, in operation, the first light-emitting elements disposed on the base substrate receive first signals and output a first image in a direction opposite of the first reflective electrode and through the base substrate,
wherein, in operation, the second light-emitting elements disposed on the wiring substrate receive second signals and output a second image different from the first image in a direction opposite of the second reflective electrode and through the wiring substrate.

10. A transparent display device comprising:
a base substrate having a first surface; and
a plurality of subpixels on the first surface of the base substrate, each subpixel including a transmissive area and a display area adjacent to the transmissive area, the display area including a micro light emitting diode (micro-LED),
wherein the transmissive area is configured to transmit external light through the display device.

11. The transparent display device of claim 10, wherein the micro-LED includes a semiconductor structure, first electrode, and a second electrode,
wherein the semiconductor structure includes a first semiconductor layer, a second semiconductor layer, and a light-emitting layer made of an inorganic material,
wherein the light-emitting layer is between the first semiconductor layer and the second semiconductor layer.

12. The transparent display device of claim 11, wherein the first electrode of the micro-LED is on the second semiconductor layer, and the second electrode of the micro-LED is on the first semiconductor layer.

13. The transparent display device of claim 10, wherein the transmissive area does not overlap with either a non-transparent material or a reflective material from a plan view.

14. The transparent display device of claim 11, comprising:
an adhesive layer on the base substrate, the adhesive layer between the micro-LED and the base substrate.

15. The transparent display device of claim 14, wherein the adhesive layer is in direct contact with the first semiconductor layer, and
wherein the adhesive layer, in operation, fixes the micro-LED to the adhesive layer.

16. The transparent display device of claim 11, comprising:
a protective layer pattern at least partially covering the micro-LED.

17. The transparent display device of claim 16, wherein the protective pattern contacts at least one of the first semiconductor layer, the light-emitting layer, and the second semiconductor layer.

18. The transparent display device of claim 12, comprising:
a protective layer pattern at least partially covering the micro-LED,
wherein the protective pattern extends from either the first electrode or the second electrode and contacts at least one of the first semiconductor layer, the light-emitting layer, and the second semiconductor layer.

19. The transparent display device of claim 18, comprising:
an adhesive layer on the base substrate, the adhesive layer between the micro-LED and the base substrate,
wherein the protective layer pattern at least partially covers the micro-LED,
wherein the protective pattern extends from either the first electrode or the second electrode and contacts at least one of the first semiconductor layer, the light-emitting layer, and the second semiconductor layer, and
wherein the protective layer pattern is spaced apart from the adhesive layer.

20. A display device comprising:
a base substrate having a first surface;
a plurality of subpixels on the first surface of the base substrate, each subpixel including a transmissive area and a display area adjacent to the transmissive area, the display area including a micro light emitting diode (micro-LED), the micro-LED including:
a semiconductor structure;
a first electrode coupled to the semiconductor structure; and
a second electrode adjacent to the first electrode and coupled to the semiconductor structure,
wherein the transmissive area of the micro-LED is configured to transmit external light therethrough such that the display device is transparent.

21. The display device of claim 20, wherein the semiconductor structure includes a first semiconductor layer, a second semiconductor layer, and a light-emitting layer,
wherein the light-emitting layer is on the first semiconductor layer and the second semiconductor layer is on the light-emitting layer, and
wherein the light-emitting layer includes an inorganic material.

22. The display device of claim 21, wherein the first electrode is on the first semiconductor layer and the second electrode is on the second semiconductor layer, and
wherein the first electrode is between the second electrode and the base substrate.

23. The display device of claim 20, wherein the base substrate includes a plurality of non-transparent materials or a plurality of reflective materials disposed thereon the base substrate, and
wherein the transmissive area of each subpixel does not overlap with both the plurality of non-transparent materials and the plurality of reflective materials from a plan view.

24. The display device of claim 22, comprising:
a protective layer pattern that extends from either the first electrode or the second electrode and at least partially covers the semiconductor structure.

25. The display device of claim 24, wherein the protective layer pattern includes a first protective layer pattern that extends from the first electrode and a second protective layer pattern that extends from the second electrode.

26. The display device of claim 25, comprising an adhesive layer on the base substrate, the adhesive layer between the micro-LED and the base substrate,
wherein at least one of the first protective layer pattern or the second protective layer pattern extends to contact the adhesive layer.

27. The display device of claim 25, comprising an adhesive layer on the base substrate, the adhesive layer between the micro-LED and the base substrate,
wherein at least one of the first protective layer pattern or the second protective layer pattern extends toward the base substrate, and
wherein the at least one of the first protective layer pattern or the second protective layer pattern is spaced apart from the adhesive layer.

28. The display device of claim 26, wherein the adhesive layer is in direct contact with the first semiconductor layer.

29. The display device of claim 20, comprising:
a wiring substrate having a second surface, the second surface of the wiring substrate facing the first surface of the base substrate;
a plurality of light-emitting elements including a first light-emitting element and a second light-emitting element having at least one micro-LED, the first light-emitting element disposed on the first surface of the base substrate and the second light-emitting element disposed on the second surface of the wiring substrate,
wherein the first light-emitting element and the second light-emitting element fully overlap with each other from a plan view.

30. The display device of claim 29, comprising:
a first reflective electrode disposed over and covering the first light-emitting element; and
a second reflective electrode disposed over and covering the second light-emitting element.

31. The display device of claim 30, comprising:
a reflective bonding layer between the first reflective electrode and the second reflective electrode,
wherein the reflective electrode and the second reflective electrode are symmetrical with respect to the reflective bonding layer.

32. The display device of claim 31, wherein the first light-emitting element and the second light-emitting element are symmetrical with respect to the reflective bonding layer.

33. The display device of claim 32, comprising:
a bonding member adjacent to at least one of the first light-emitting element or the second light-emitting element and between the base substrate and the wiring substrate, the bonding member including a spacer pattern, a conductive connection pattern on the spacer pattern, and an adhesive pattern on the conductive connection pattern,
wherein the bonding member, in operation, bonds the base substrate to the wiring substrate.

34. The display device of claim 33, comprising a refractive index matching layer in a space between the bonding member and the first and second reflective electrodes, the refractive index matching layer including a transparent material.

35. The display device of claim 34, comprising a first link wiring line and a second link wiring line, the first link wiring line and the second link wiring line being adjacent to the first and second light-emitting elements,
wherein the bonding member includes one or more bonding members, each of the one or more bonding members respectively disposed on the first link wiring line and the second link wiring line to electrically connect the wiring substrate to the base substrate.

36. The display device of claim 35, comprising:
a first circuit film disposed on one side end of the wiring substrate and electrically connected to the first link wiring line;
a first integrated circuit chip for transmitting first signals to the first light-emitting elements disposed on the base substrate, the first integrated circuit chip disposed on the first circuit film;
a first printed circuit board electrically connected to the first circuit film;
a second circuit film disposed on the other side end opposite to the one side end of the wiring substrate, and electrically connected to the second link wiring lines;
a second integrated circuit chip for transmitting second signals to the second light-emitting elements disposed on the wiring substrate, the second integrated circuit chip disposed on the second circuit film; and
a second printed circuit board electrically connected to the second circuit film.
